(19) United States
(12) Patent Application Publication
(10) Pub. No.: US 2012/0251747 A1
(43) Pub. Date: Oct. 4, 2012

(54) HOUSING AND METHOD FOR MANUFACTURING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); JUAN ZHANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/271,378

(22) Filed: Oct. 12, 2011

(30) Foreign Application Priority Data
Apr. 1, 2011 (CN) 201110081324.9

(51) Int. Cl. B32B 1/02; C23C 14/34

(52) U.S. Cl. 428/34.6; 204/192.15; 428/34.1; 428/35.7

(57) ABSTRACT

A housing includes a substrate and a metallic coating. The metallic coating is deposited on the substrate. The metallic coating comprises an equal number of alternating first metallic layers and second metallic layers. The first metallic layers have a refractivity that is different from the refractivity of the second metallic layers.

### BACKGROUND

1. Technical Field

The disclosure generally relates to housings and method for manufacturing the housings.

2. Description of Related Art

With the development of wireless communication and information processing technology, portable electronic devices, such as mobile phones and laptop computers are now widely used. The external appearance of the housing of the portable electronic device can be one of the key factors in attracting consumers.

A typical way to achieve an decorative appearance is by coating a non-conductive layer on the housing. However, the non-conductive layer only provides a single color, i.e., a metallic appearance, for the housing.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary housing and method for manufacturing the housing. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an embodiment of a housing for an electronic device.

FIG. 2 is a schematic view of a magnetron sputtering coating machine for manufacturing the housing in FIG. 1.

### DETAILED DESCRIPTION

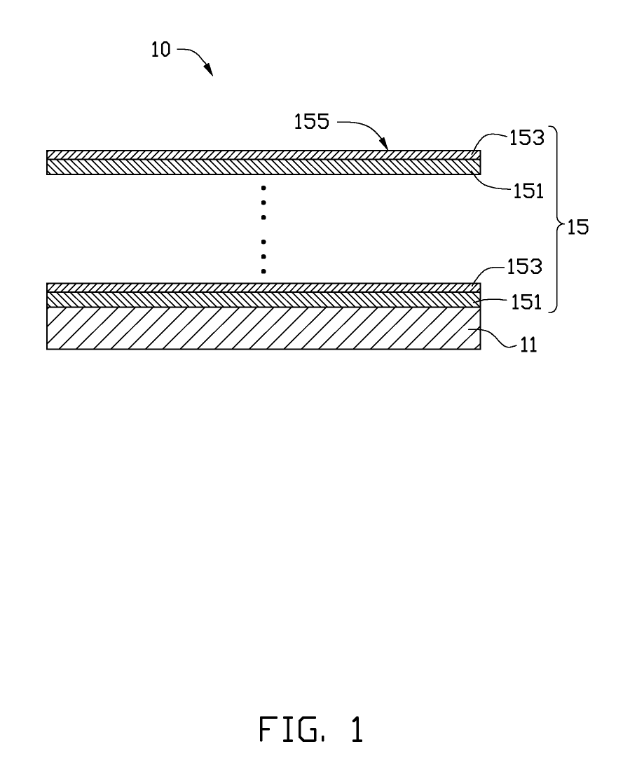

Referring to FIG. 1, a housing 100 includes a substrate 11 and a metallic coating 15 deposited on the substrate 11. The housing 100 may be a housing of an electronic device.

The substrate 11 may be molded from a transparent thermoplastic material, such as polycarbonate (PC), polymethyl Methacrylate (PMMA), polyamide (PA), or any combination thereof. The substrate 11 may also be made of glass, metal or ceramic.

The metallic coating 15 is formed on the substrate 11 by vacuum deposition, such as vacuum sputtering or vacuum evaporation. The metallic coating 15 has a thickness between about 0.5 micrometers and about 2 micrometers, to ensure the transmission of communication signals through the housing 10 when the housing 10 is a housing of a communication device.

The metallic coating 15 includes an equal number of alternating first metallic layers 151 and second metallic layers 153. The number of the first metallic layers 151 and the second metallic layers 153 may be between 6 and 10 each (i.e., each, not total). The metallic coating 15 bonds/contacts with the substrate 11 through one first metallic luster layer 151, and an outer layer of the metallic coating 15, which may be a first metallic layer 151 or a second metallic layer 153. The first metallic layers 151 have different refractivity than that of the second metallic layers 153. In this exemplary embodiment, the first metallic layers 151 may be made of titanium oxide, iron oxide, zirconium oxide, tin oxide, or zinc oxide, The second metallic layers 153 may be made of aluminum oxide or silicone oxide. Due to the difference in the refractivity of the first metallic layers 151 and the second metallic layers 153, the metallic coating 15 has a high reflectivity to light illuminated on its outer surface 155. As a result, when the metallic coating 15 is struck by light, the outer surface 155 can present a multi-color appearance. Thus, the housing can be can present a multi-color appearance when observing from the outer surface 155.

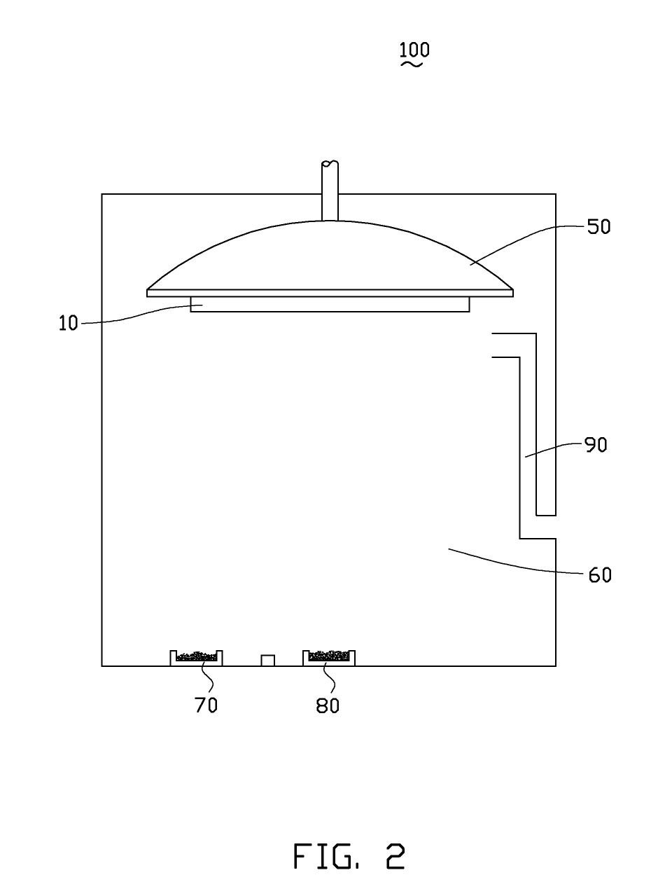

Referring to FIGS. 1 and 2, a method for manufacturing the housing 10 includes at least the following steps.

Providing a substrate 11. The substrate 11 may be made of plastic, glass or metal.

Pre-treating the substrate 11. The substrate 11 is washed with a solution (e.g., alcohol or acetone) in an ultrasonic cleaner, to remove impurities, such as grease or dirt. The substrate 11 is dried then plasma cleaned, to further remove impurities. The substrate 11 is retained on a rotating bracket 50 in a vacuum chamber 60 of a magnetron sputtering coating machine 100 evacuated to about 8.0×10⁻³ Pa. Argon gas having a purity of about 99.999% is fed into the vacuum chamber 60 at a flow rate about 100 Standard Cubic Centimeters per Minute (sccm) to 500 sccm from a gas inlet 90. A bias voltage applied to the substrate 11 is between −500 volts (V) to −800 V for about 3 minutes (min) −10 min so the argon gas is ionized to plasma. The plasma then strikes the surface of the substrate 11 to clean the surface of the substrate 11 As a result, the bonding force between the substrate 11 and the metallic coating 15 is enhanced.

A metallic coating 15 is deposited on the substrate 11. First, a metallic layer 151 and a second metallic layer 153 are alternatively deposited on the substrate 11 until an equal number of about 6 to 10 of each first metallic layers 153 and second metallic layers 153 are deposited.

During the deposition of the first metallic layers 151, the temperature in the vacuum chamber 60 is adjusted between 50 Celsius degree (° C.) and 180° C. Pure argon is fed into the vacuum chamber 60 at a flow rate about 100 sccm to about 300 sccm from the gas inlet 90. Oxygen is fed into the vacuum chamber 60 at a flow rate about 30 sccm and about 200 sccm from the gas inlet 90. A bias voltage applied to the substrate 11 is between about −50 V and −200 V. A first target 70, such as titanium target, iron target, zirconium target, tin target, or zinc target, in the vacuum chamber 60 is evaporated at a power of about 2 kW to about 8 kW for about 5 min −50 min, to deposit a first metallic layers 151 on the substrate 11.

During depositing the second metallic layers 153, the temperature in the vacuum chamber 60 is adjusted between 50° C. and 180° C. Pure argon is fed into the vacuum chamber 60 at a flow rate between about 100 sccm and about 300 sccm from the gas inlet 90. Oxygen is fed into the vacuum chamber 60 at a flow rate between about 30 sccm to about 200 sccm from the gas inlet 90. A bias voltage is applied to the substrate 11 at about −50 V and −200 V. A second target 80, such as aluminum target or silicone target, in the vacuum chamber 60 is evaporated in a power between about 2 kW to about 8 kW for about 5 min-60 min, to deposit a second metallic layers 153 on the first metallic layers 151.

### EXAMPLES

Experimental examples of the present disclosure are following

### Example 1

1. The substrate 11 is made of aluminosilicate glass.

The substrate 11 is retained on the rotating bracket 50 in the vacuum chamber 60. Pure argon is fed into the vacuum chamber 60 at a flow rate about 500 sccm from the gas inlet 90. A bias voltage of about −500 V is applied to the substrate 11 for about 8 min.

2. A first metallic layers 151 is deposited on the substrate.

The temperature in the vacuum chamber 60 is adjusted to 500° C. Pure argon is fed into the vacuum chamber 60 at a flow rate about 200 sccm from the gas inlet 90. Oxygen is fed into the vacuum chamber 60 at a flow rate about 30 sccm from the gas inlet 90. The bias voltage applied to the substrate 11 is about −70 V. The first target 70, zinc target, is evaporated at a power about 8 kW for about 10 min in the vacuum chamber 60, to deposit a first metallic layers 151 having a thickness of 50 nanometers on the substrate 11.

3. A second metallic layers 153 is deposited on the first metallic layers 151.

The temperature in the vacuum chamber 60 is adjusted 100° C. Pure argon is fed into the vacuum chamber 60 at a flow rate about 200 sccm from the gas inlet 90. Oxygen is fed into the vacuum chamber 60 at a flow rate about 50 sccm from the gas inlet 90. A bias voltage applied to the substrate 11 is about −70 V. A second target, such as zinc target, is evaporated in the vacuum chamber 60 at a power about 6 kW for about 30 min, to deposit a second metallic layer 153 having a thickness of 70 nanometers on the substrate 11.

4. Alternatively repeating the second step and the third step six times.

### Example 2

1. The substrate 11 made of type 304 stainless steel.

The substrate 11 is retained on the rotating bracket 50 in the vacuum chamber 60. Pure argon is fed into the vacuum chamber 60 at a flow rate about 500 sccm from the gas inlet 90. A bias voltage applied to the substrate 11 is −700 V for about 5 min.

2. A first metallic layers 151 is deposited on the substrate.

The temperature in the vacuum chamber 60 is adjusted 100° C. Pure argon is fed into the vacuum chamber 60 at a flow rate about 200 sccm from the gas inlet 90. Oxygen is fed into the vacuum chamber 60 at a flow rate about 30 sccm from the gas inlet 90. A bias voltage applied to the substrate 11 is about −70 V. A first target 70, such as zinc target, in the vacuum chamber 60 is evaporated in a power about 8 kW for about 15 min, to deposit a first metallic layers 151 having a thickness of 65 nanometers on the substrate 11.

3. A second metallic layers 153 is deposited on the first metallic layers 151.

The temperature in the vacuum chamber 60 is adjusted 120° C. Pure argon is fed into the vacuum chamber 60 at a flow rate about 200 sccm from the gas inlet 90. Oxygen is fed into the vacuum chamber 60 at a flow rate about 50 sccm from the gas inlet 90. A bias voltage applied to the substrate 11 is about −70 V. A second target 80 comprising a silicon target and a sin target, in the vacuum chamber 60 is evaporated, the silicon target is evaporated in a power about 6 kW and the sin target is evaporated in a power about 8 kW for about 35 min, to deposit a second metallic layers 153 having a thickness of 70 nanometers on the substrate 11.

4. Alternatively repeating the second step and the third step eight times.

### Example 3

1. The substrate 11 made of aluminosilicate Glass.

The substrate 11 is retained on the rotating bracket 50 in the vacuum chamber 60. Pure argon is fed into the vacuum chamber 60 at a flow rate about 500 sccm from the gas inlet 90. A bias voltage applied to the substrate 11 is −500 V for about 8 min.

2. A first metallic layers 151 is deposited on the substrate.

The temperature in the vacuum chamber 60 is adjusted 100° C. Pure argon is fed into the vacuum chamber 60 at a flow rate about 200 sccm from the gas inlet 90. Oxygen is fed into the vacuum chamber 60 at a flow rate about 30 sccm from the gas inlet 90. A bias voltage applied to the substrate 11 is about −70 V. A first target 70, such as zinc target, in the vacuum chamber 60 is evaporated in a power about 8 kW for about 15 min, to deposit a first metallic layers 151 having a thickness of 65 nanometers on the substrate 11.

3. A second metallic layers 153 is deposited on the first metallic layers 151.

The temperature in the vacuum chamber 60 is adjusted 120° C. Pure argon is fed into the vacuum chamber 60 at a flow rate about 200 sccm from the gas inlet 90. Oxygen is fed into the vacuum chamber 60 at a flow rate about 50 sccm from the gas inlet 90. A bias voltage applied to the substrate 11 is about −70 V. A second target 80 comprising a silicon target, a sin target and an iron target, in the vacuum chamber 60 is evaporated, the silicon target is evaporated in a power about 5 kW, the sin target is evaporated in a power about 8 kW and the iron target is evaporated in a power about 6 kW for about 20 min, to deposit a second metallic layers 153 having a thickness of 75 nanometers on the substrate 11.

4. Alternatively repeating the second step and the third step ten times.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing, comprising:
a substrate; and
a metallic coating deposited on the substrate, the metallic coating comprising an equal number of alternating first metallic layers and second metallic layers;
wherein the first metallic layers have a refractivity that is different from the refractivity of the second metallic layers.

2. The housing as claimed in claim 1, wherein the substrate is made of thermoplastic, glass, metal or ceramic.

3. The housing as claimed in claim 1, wherein the metallic coating has a thickness between about 0.5 micrometers and about 2 micrometers so communication signal are capable of transmitting through the housing.

4. The housing as claimed in claim 1, wherein the equal number of the first metallic layers and the second metallic layers is between 6 and 10 of each.

5. The housing as claimed in claim 1, wherein the metallic coating bonds with the substrate by one first metallic layer.

6. The housing as claimed in claim 1, wherein an outer layer of the metallic is one of first metallic layers or one of second metallic layers.

7. The housing as claimed in claim 1, wherein the first metallic layers is made of titanium oxide, iron oxide, zirconium oxide, tin oxide, or zinc oxide.

8. The housing as claimed in claim 1, wherein the second metallic layers is made of aluminum oxide or silicone oxide.

9. A method for manufacturing a housing, the method comprising:
providing a substrate;
depositing an metallic coating on the substrate by vacuum deposition;
wherein the metallic coating comprises an equal number of alternating first metallic layers and second metallic layers, and the first metallic layers have a refractivity that is different from the refractivity of the second metallic layers.

10. The method of claim 9, wherein the substrate is made of plastic, glass or metal.

11. The method of claim 9, wherein during the metallic coating on the substrate, a first metallic layer and a second metallic layer are alternatively deposited on the substrate until 6 to 10 second metallic layers and an equal number of second metallic layers are deposited.

12. The method of claim 11, wherein during depositing the first metallic layers, the substrate is retained in a vacuum chamber; the temperature in the vacuum chamber is adjusted between 50° C. and 180° C.; pure argon is fed into the vacuum chamber at a flow rate between about 100 sccm and about 300 sccm; oxygen is fed into the vacuum chamber at a flow rate between about 30 sccm and about 200 sccm; a bias voltage applied to the substrate is between about −50 V and −200 V; A first target in the vacuum chamber is evaporated in a power between about 2 kW to about 8 kW for about 5-50 min, to deposit the first metallic layers on the substrate.

13. The method of claim 12, wherein the first target is titanium target, iron target, zirconium target, tin target, or zinc target.

14. The method of claim 12, wherein during depositing the second metallic layers, the temperature in the vacuum chamber is adjusted between 50° C. and 180° C.; pure argon is fed into the vacuum chamber at a flow rate between about 100 sccm and about 300 sccm; oxygen is fed into the vacuum chamber at a flow rate between about 30 sccm and about 200 sccm; a bias voltage applied to the substrate is between about −50 V and −200 V; a second target 80 in the vacuum chamber is evaporated in a power between about 2 kW to about 8 kW for about 5-60 min, to deposit the second metallic layers on the first metallic layers.

15. The method of claim 14, wherein the second target is aluminum target or silicone target.
